(19) United States
(12) Patent Application Publication
(10) Pub. No.: US 2025/0372548 A1
(43) Pub. Date: Dec. 4, 2025

(54) INDUCTOR MODULE WITH PACKAGED SEMICONDUCTOR DIE

(71) Applicant: TEXAS INSTRUMENTS INCORPORATED, Dallas, TX (US)

(72) Inventors: Jonathan Andrew MONTOYA, Dallas, TX (US); Frank STEPNIAK, Richardson, TX (US); Christopher Daniel MANACK, Flower Mound, TX (US); Makarand Ramkrishna KULKARNI, Plano, TX (US); Leslie Edward STARK, Heath, TX (US)

(21) Appl. No.: 18/680,628

(22) Filed: May 31, 2024

(51) Int. Cl. H01L 23/64; H01L 21/56; H01L 23/29; H01L 23/31; H01L 23/498; H01L 25/16

(52) U.S. Cl. CPC H01L 23/645; H01L 21/565; H01L 23/295; H01L 23/3107; H01L 23/49827; H01L 23/642; H01L 25/165

(57) ABSTRACT

In examples, a semiconductor package comprises a substrate; a second semiconductor package coupled to the substrate, the second semiconductor package comprising a semiconductor die including first metal contacts coupled to second metal contacts of the second semiconductor package; a magnetic mold compound covering the substrate and the second semiconductor package, the magnetic mold compound contacting the second metal contacts; and an inductor coil having first and second terminals coupled to the substrate, the second semiconductor package in between the first and second terminals of the inductor coil.

### BACKGROUND

Semiconductor wafers are circular pieces of semiconductor material, such as silicon, that are used to manufacture semiconductor chips. Generally, complex manufacturing processes are used to form numerous integrated circuits on a single wafer. The formation of such circuits on a wafer is called fabrication. After wafer fabrication, the wafer is cut into multiple pieces, called semiconductor dies, with each die containing one of the circuits. The cutting, or sawing, of the wafer into individual dies is called singulation. An individual die is then coupled to a die pad and to conductive terminals, sometimes called “leads.” The resulting structure is subsequently covered with a mold compound to produce a package.

### SUMMARY

In examples, a semiconductor package comprises a substrate; a second semiconductor package coupled to the substrate, the second semiconductor package comprising a semiconductor die including first metal contacts coupled to second metal contacts of the second semiconductor package; a magnetic mold compound covering the substrate and the second semiconductor package, the magnetic mold compound contacting the second metal contacts; and an inductor coil having first and second terminals coupled to the substrate, the second semiconductor package in between the first and second terminals of the inductor coil.

In examples, a method for manufacturing a semiconductor package comprises coupling a semiconductor die to a lead frame, the semiconductor die including first metal contacts having a first pitch; covering the semiconductor die and the lead frame with a mold compound to form a second package, the lead frame including second metal contacts having a second pitch; coupling the second package to a substrate; and covering the semiconductor package and the substrate with a magnetic mold compound. The second pitch prevents metal ions in the magnetic mold compound from causing current flow between successive ones of the second metal contacts at any operational voltage of the semiconductor package, the second pitch larger than the first pitch.

### BRIEF DESCRIPTION OF THE DRAWINGS

FIG. 1 is a block diagram of an electronic device including an inductor module with a packaged semiconductor die, in accordance with various examples.

FIGS. 2A-4 are perspective views of inductor modules with packaged semiconductor dies, in accordance with various examples.

FIG. 5 is a top-down view of an inductor module with a packaged semiconductor die, in accordance with various examples.

FIG. 6 is a profile view of an inductor module with a packaged semiconductor die, in accordance with various examples.

FIG. 7 is a perspective view of an inductor module with a packaged semiconductor die, in accordance with various examples.

FIG. 8 is a profile view of an inductor module with a packaged semiconductor die, in accordance with various examples.

FIG. 9 is a perspective view of an inductor module with a packaged semiconductor die, in accordance with various examples.

FIG. 10 is a flow diagram of a method for manufacturing an inductor module with a packaged semiconductor die, in accordance with various examples.

FIGS. 11A-16C are a process flow of a method for manufacturing an inductor module with a packaged semiconductor die, in accordance with various examples.

### DETAILED DESCRIPTION

Some electronic devices, such as inductor modules, must be designed and manufactured according to certain specifications (e.g., design rules) to ensure proper operation. For example, such specifications are useful to avoid undue mechanical stress within the device that can cause various problems, such as delamination, within the package. These specifications are also useful to mitigate the risk of electromagnetic interference between components, electrical shorts or leakage between adjacent conductive components (particularly in the context of magnetic mold compounds), undue thermal stress due to the proximity of components to each other, and so on. Compliance with the specifications, however, is tedious. For instance, a particular inductor module may include a semiconductor die and various other components (e.g., passive components such as inductors and capacitors) and may be engineered according to the appropriate specifications. However, if it is then desirable to swap the semiconductor die for a different semiconductor die while keeping the remaining components of the inductor module the same, then the design and qualification procedures must be repeated, which is tedious, time-consuming, and expensive.

This disclosure describes various examples of a semiconductor package, such as an inductor module, that includes a second package covering a semiconductor die. After the qualification process has been completed to ensure the design of the semiconductor package meets specifications, the process does not have to be repeated in the future, even if a new semiconductor die is substituted for the semiconductor die that was part of the qualified design. This is because the second package in which the semiconductor die is included interfaces with the remainder of the semiconductor package, and thus any substitutions that occur inside the second package (e.g., semiconductor die substitutions) do not affect interactions between the second package and the remaining contents of the semiconductor package. In examples, a semiconductor package comprises a substrate and a second semiconductor package coupled to the substrate. The second semiconductor package comprises a semiconductor die including first metal contacts coupled to second metal contacts of the second semiconductor package. The package also includes a magnetic mold compound (i.e., a mold compound with metal (e.g., iron) particles distributed throughout the mold compound, which is distinguishable from a mold compound with a singular magnetic core) covering the substrate and the second semiconductor package. The magnetic mold compound contacts the second metal contacts. The package also includes an inductor coil having first and second terminals coupled to the substrate, with the second semiconductor package in between the first and second terminals of the inductor coil.

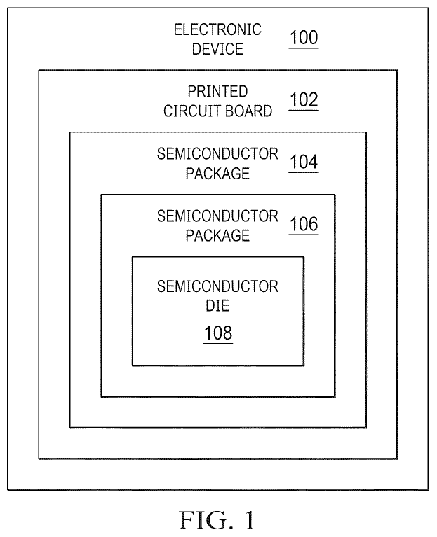

FIG. 1 is a block diagram of an electronic device including an inductor module with a packaged semiconductor die, in accordance with various examples. In particular, FIG. 1 depicts an electronic device 100, which may be any suitable device, such as an automobile, an aircraft, a watercraft, a spacecraft, a video game console, a smartphone, an entertainment device, an appliance, a laptop computer, a desktop computer, a tablet, a notebook, or any other suitable type of device or system. The electronic device 100 may include a printed circuit board (PCB) 102. Various components may be coupled to the PCB 102, such as the semiconductor package 104. Other components, such as circuitry that is configured to interact with the semiconductor package 104, may also be coupled to the PCB 102.

In examples, the semiconductor package 104 comprises a passive component module. In examples, the semiconductor package 104 comprises an inductor module. The scope of this disclosure is not limited to semiconductor packages 104 that are passive component modules or inductor modules. The semiconductor package 104 may include various components such as one or more inductors and one or more capacitors. In addition, the semiconductor package 104 includes a semiconductor package 106. The semiconductor package 106 comprises a non-magnetic mold compound, while the semiconductor package 104 comprises a magnetic mold compound, with the only mold compound portion of the semiconductor package 104 that is non-magnetic is that which is part of the semiconductor package 106. The semiconductor package 106 includes a semiconductor die 108, which is configured for any suitable purpose. In examples, the semiconductor die 108 is configured to use one or more of the passive components within the semiconductor package 104.

The semiconductor package 104, including its contents, is designed to have a layout that is compliant with all appropriate specifications (e.g., design rules) and that would pass qualification testing. The semiconductor package 104 can then be re-designed such that the semiconductor die within the semiconductor package 106 is changed, and this re-design can be accomplished without performing additional qualification procedures. The semiconductor package 104 is also advantageous because a semiconductor die 108 with a small geometry (e.g., small pitch between conductive terminals on the semiconductor die 108) can be used without risking current leakage or electrical shorts due to the metallic components (e.g., iron ions) of the magnetic mold compound of the semiconductor package 104.

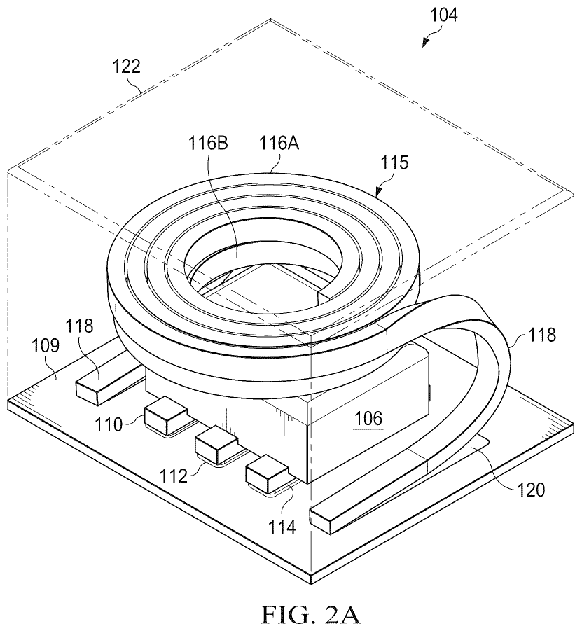

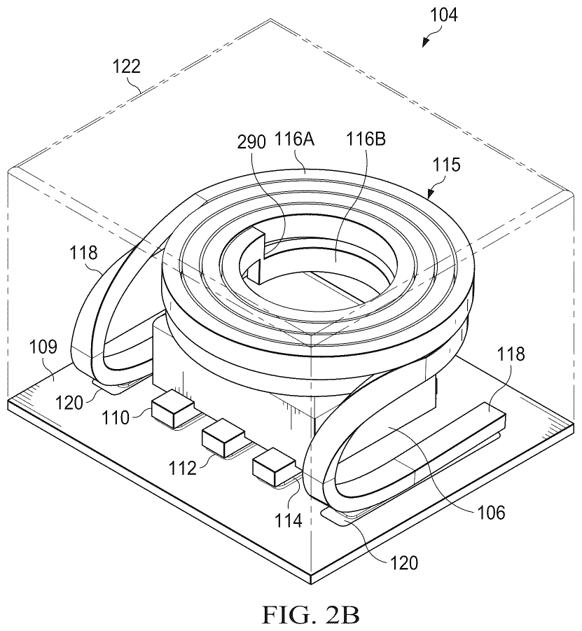

FIGS. 2A-4 are perspective views of inductor modules with packaged semiconductor dies, in accordance with various examples. More specifically, FIG. 2A is a perspective view of an example semiconductor package 104. The semiconductor package 104 comprises an example semiconductor package 106 and a substrate 109 to which the semiconductor package 106 is coupled. Specifically, the semiconductor package 106 includes conductive terminals 110 (e.g., leads) that are coupled to conductive terminals 112 on the substrate 109 by way of solder 114. The semiconductor package 104 includes an inductor 115 having a coil portion 116A, a coil portion 116B, and terminals 118 (e.g., two terminals 118). A first terminal 118 is coupled to a conductive terminal 120 by way of solder 114, and a second terminal 118 is coupled to another conductive terminal 120 (not clearly visible in FIG. 2A) by way of solder 114 (not clearly visible in FIG. 2A). The coil portion 116A terminates at one of the terminals 118 and the coil portion 116B terminates at the other terminal 118, with the coil portions 116A, 116B being coupled to each other by a connecting member 290 (FIG. 2B). As shown in FIGS. 2A and 2B, the coil portion 116A has a spiral shape that loops multiple times in the x-y plane, and the coil portion 116B also has a spiral shape that loops multiple times in the x-y plane, with the coil portions 116A, 116B being in different horizontal planes (i.e., the coil portion 116A is farther from the substrate 109 than is the coil portion 116B). As also shown in FIGS. 2A and 2B, the terminals 118 twist in three-dimensional space, such that the terminal 118 that comes off of the coil portion 116A has an inner surface facing a center of the coil portion 116A that faces upward at the distal end of that terminal 118, and such that the terminal 118 that comes off of the coil portion 116B has an inner surface facing a center of the coil portion 116B that faces upward at the distal end of that terminal 118. The coil portions 116A, 116B may have any suitable number of turns, and in examples, the coil portions 116A, 116B have the same or different numbers of turns. A magnetic mold compound 122 covers the structures of the semiconductor package 104 and contacts (i.e., directly touches, without any intervening material(s) in between) at least the conductive terminals 110, while a non-magnetic mold compound covers the semiconductor package 106. The magnetic mold compound 122 contains iron ions at a packing fraction (i.e., a measure of how densely iron ions are packed within the mold compound and is defined as the ratio of the volume occupied by iron ions to the total volume of the mold compound) ranging from 70% to 95%, with a packing fraction below this range being disadvantageous because of unacceptably low permittivity (i.e., higher packing fractions achieve higher permittivities), and with a packing fraction above this range being disadvantageous because of unacceptably poor mold flowability (i.e., lower packing fractions achieve superior mold flow). In examples, the magnetic mold compound 122 operates as a magnetic core for the inductor 115 and the coil portions 116A, 116B. The conductive terminals 110 of the semiconductor package 106 have a pitch ranging from 0.4 mm to 0.5 mm. The pitch of the conductive terminals 110 has a minimum defined by one or more properties of the magnetic mold compound 122, such as metal ion conductivity, metal ion mobility, metal ion density, and metal ion distribution. The pitch of the conductive terminals 110 is adequately large to prevent leakage and shorting that would otherwise occur between consecutive ones of the conductive terminals 110 by way of one or more metal ions in the magnetic mold compound 122. Relatively small conductive terminal 110 widths less than 0.2 mm will limit maximum applied current, which is disadvantageous in multiple applications, and relatively small inter-terminal 110 spaces less than 0.2 mm will limit the maximum voltage difference that is applied to consecutively adjacent terminals 110, which is disadvantageous in multiple applications. Consecutive conductive terminals of the semiconductor die (not expressly shown in FIGS. 2A and 2B) inside the semiconductor package 106 have a pitch that is smaller than that of the conductive terminals 110, ranging from 100 microns to 400 microns, with terminal widths of approximately 50 microns and inter-terminal spacing ranging from 50 microns to 300 microns. Inter-terminal spacing on the low end of the 50 micron-300 micron range (i.e., up to 75 microns) is useful when there is no voltage drop between consecutively adjacent terminals, and inter-terminal spacing on the high end of the 50 micron-300 micron range (i.e., between 75 and 300 microns) is useful for larger voltage drops between consecutively adjacent terminals, with the inter-terminal spacing progressively increasing from 75 microns to 300 microns as the voltage drops between consecutively adjacent terminals increases.

The semiconductor package 106 may be any suitable type of package. In examples, the semiconductor package 106 is a small outline transistor (SOT) package having leads that are flat, although the scope of this disclosure is not limited to any particular type of package or lead style. Other types of packages, such as quad-flat no-lead (QFN) packages, ball grid array (BGA) packages, dual in-line packages (DIP), and other types of leads, such as gullwing leads, are contemplated and included in the scope of this disclosure.

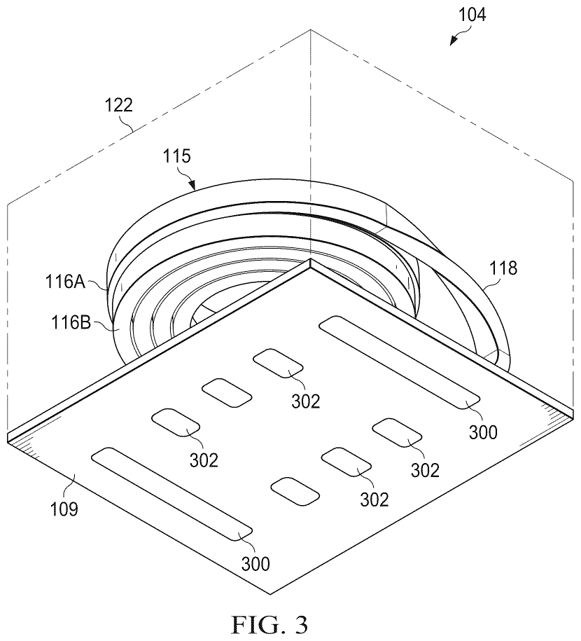

FIG. 3 is another perspective view of the structure of FIGS. 2A and 2B. The view of FIG. 3 depicts a bottom side of the substrate 109. In particular, the substrate 109 includes conductive terminals 300 and 302. The conductive terminals 300 may be coupled to conductive terminals 120, and the conductive terminals 302 may be coupled to conductive terminals 112. Other connections between the various conductive terminals are contemplated and included in the scope of this disclosure, such as one or more of the conductive terminals 300 coupling to one or more of the conductive terminals 112, and one or more of the conductive terminals 302 coupling to one or more of the conductive terminals 120. Similarly, one or more of the conductive terminals 300 may be coupled to one or more of the conductive terminals 302, and one or more of the conductive terminals 112 may be coupled to one or more of the conductive terminals 120. The conductive terminals 300, 302 may be soldered or otherwise coupled to the PCB 102 (FIG. 1).

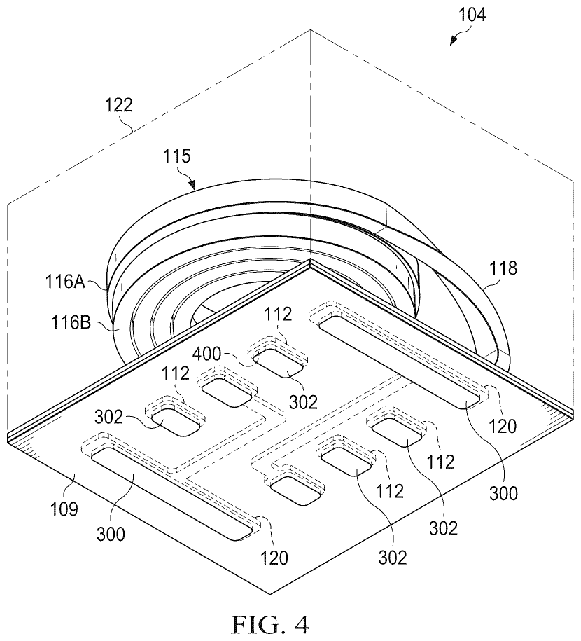

FIG. 4 is another perspective view of the structure of FIGS. 2A, 2B, and 3. The view of FIG. 4 is similar to that of FIG. 3, except that FIG. 4 additionally shows conductive traces embedded within the substrate 109. For example, FIG. 4 depicts conductive traces 400 (e.g., vertical metal vias) that may extend between any combination of conductive terminals 112, 120, 300, and 302. The conductive traces 400 facilitate communication between the various conductive terminals 112, 120, 300, and 302 in any combination.

The substrate 109 may be any suitable type of substrate. In examples, the substrate 109 is a printed circuit board (PCB). In other examples, the substrate 109 is not a PCB. Rather, in such examples, the substrate 109 has multiple metal layers coupled by vertical metal vias, with the various metal layers and vias covered by a build-up film, such as AJINOMOTO® build-up film (ABF). In examples, the substrate 109 is manufactured by forming one or more metal layers (e.g., by a plating technique), depositing a build-up film on the one or more metal layers, grinding or otherwise thinning the resulting structure, and then repeating the process. The metal layers, including the vertical vias, may be formed in any desired structural configuration. Such a substrate 109 differs from a PCB because this type of substrate 109 includes multiple metal layers that are covered by a solid, tangible dielectric material such as build-up film, whereas the PCB may contain multiple layers of printed circuit board that may not be separated by a dielectric material other than air. Other than the example substrates 109 described above, the substrate 109 also may include Flame Retardant-4 (FR4), embedded trace substrate (ETS), molded interconnect substrate (MIS), and etched lead frames.

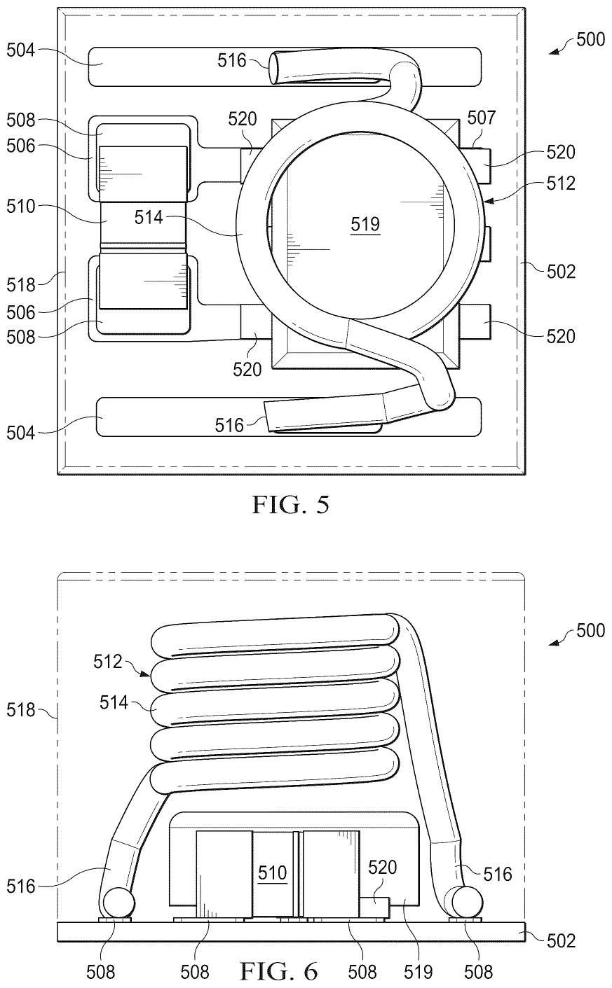

FIG. 5 is a top-down view of an inductor module with a packaged semiconductor die, in accordance with various examples. In particular, FIG. 5 shows an example semiconductor package 500 (e.g., inductor module) comprising a substrate 502 having conductive terminals 504, 506, and 507. The description provided above for the substrate 109 also applies to the substrate 502, and thus the substrate 502 is not described again in detail here. A capacitor 510 is coupled to the conductive terminals 506 by solder 508. As shown, each of the conductive terminals 506 has multiple segments: a larger segment where the capacitor 510 is coupled, and a smaller segment extending away from the capacitor 510 and toward a center of the substrate 502. The width of the larger segment of each conductive terminal 506 (measured parallel to the length of the capacitor 510) is greater than the width of the smaller segment of that conductive terminal 506 (measured parallel to the length of the capacitor 510). Stated another way, each conductive terminal 506 is wide in the area where that conductive terminal 506 is coupled to the capacitor 510, and then becomes narrower as that conductive terminal 506 extends away from the capacitor 510.

The semiconductor package 500 may include an inductor 512 coupled to the substrate 502. Specifically, the inductor 512 includes a coil portion 514 and terminals 516 extending from opposing ends of the coil portion 514. One of the terminals 516 is coupled to one of the conductive terminals 504, while another one of the terminals 516 is coupled to the other one of the conductive terminals 504. The terminals 516 may be coupled to the conductive terminals 504 by solder 508, for example. The terminals 516 twist in three-dimensional space, as specifically shown in the drawings. The coil portion 514 differs from the coil portions 116A, 116B (FIG. 2A) in that the coil portion 514 includes multiple loops (or turns) that are stacked vertically in the z direction, as shown. Further, the inductor 512 includes a single coil portion 514, while the inductor 115 of FIG. 2A includes multiple coil portions 116A, 116B that are coupled to each other, as described above.

The semiconductor package 500 further includes a semiconductor package 519. The semiconductor package 519 includes multiple conductive terminals (leads) 520, some of which are coupled to the conductive terminals 506, and the remainder of which are coupled to the conductive terminals 507. Such connections may include solder 508. The semiconductor package 500 includes a non-magnetic mold compound, while the outermost mold compound of the semiconductor package 500 is a magnetic mold compound 518. The magnetic mold compound 518 has a packing fraction of iron ions as described above with reference to magnetic mold compound 122, with the same advantages and disadvantages associated with variance outside the prescribed packing fraction range as described above. In examples, the magnetic mold compound 518 operates as a magnetic core for the inductor 512 and the coil portion 514. The conductive terminals 520 of the semiconductor package 500 have a pitch, terminal width, and inter-terminal spacing as described above with reference to the conductive terminals 110, with the same advantages and disadvantages associated with variance outside the prescribed ranges as described above. The pitch of the conductive terminals 520 has a minimum defined by one or more properties of the magnetic mold compound 518, such as metal ion conductivity, metal ion mobility, metal ion density, and metal ion distribution. The pitch of the conductive terminals 520 is adequately large to prevent leakage and shorting that would otherwise occur between consecutive ones of the conductive terminals 520 by way of one or more metal ions in the magnetic mold compound 518. Consecutive conductive terminals of the semiconductor die (not expressly shown in FIG. 5) inside the semiconductor package 519 have a pitch that is smaller than that of the conductive terminals 520. The pitch, terminal widths, and inter-terminal spacing of the conductive terminals of the semiconductor die within the semiconductor package 519 are the same as those described above for the conductive terminals of the semiconductor die within the semiconductor package 106, with the same attendant advantages and disadvantages.

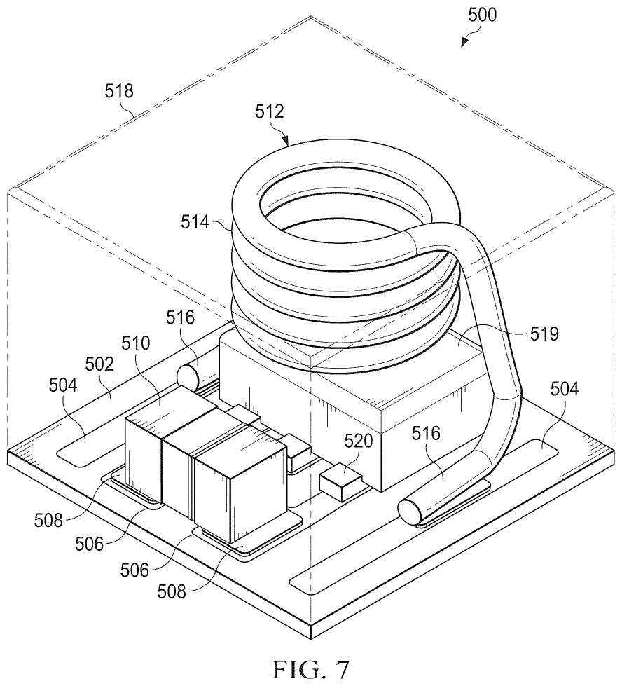

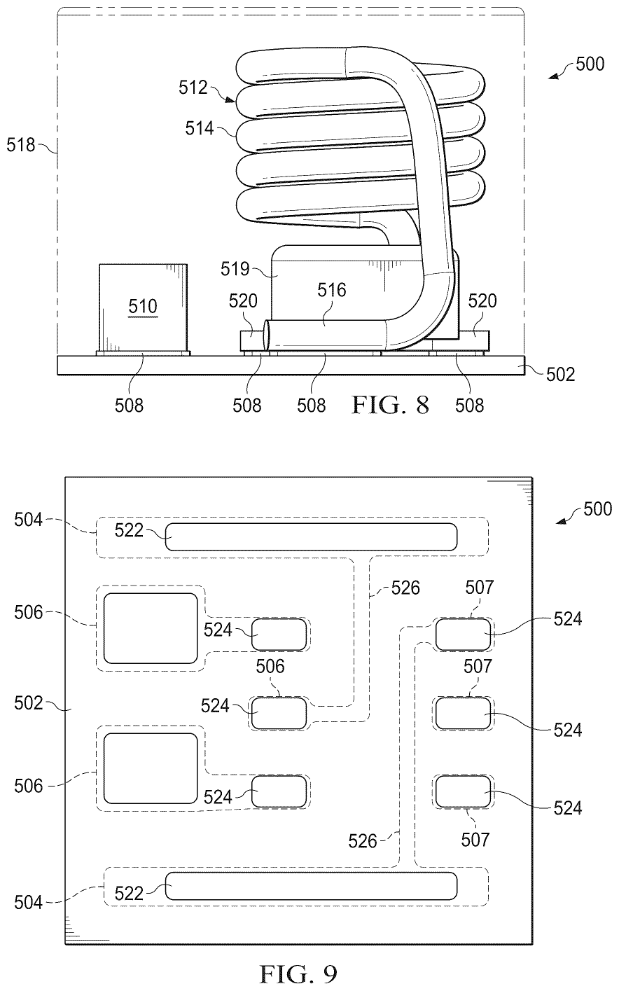

FIG. 6 is a profile view of the semiconductor package 500 of FIG. 5, in accordance with various examples. FIG. 7 is a perspective view of the semiconductor package 500 of FIG. 5, in accordance with various examples. FIG. 8 is another profile view of the semiconductor package 500 of FIG. 5, in accordance with various examples. FIG. 9 is a bottom view of the semiconductor package 500 of FIG. 5, in accordance with various examples. As FIG. 9 shows, a bottom surface of the substrate 502 may include conductive terminals 522, 524. These conductive terminals 522, 524 are useful to couple to a PCB, such as the PCB 102 (FIG. 1), for example. The conductive terminals 522, 524 on the bottom surface of the substrate 502 and the conductive terminals 504, 506, and 507 on the top surface of the substrate 502 may couple to each other in any suitable combination. For example, each of the conductive terminals 522, 524 may couple to each other and/or to one or more of the conductive terminals 504, 506, and 507, in any combination. Similarly, each of the conductive terminals 504, 506, and 507 may couple to each other and/or to one or more of the conductive terminals 522, 524, in any combination. Conductive traces 526 embedded within the substrate 502 may facilitate one or more such couplings between the various conductive terminals 504, 506, 507, 522, and 524.

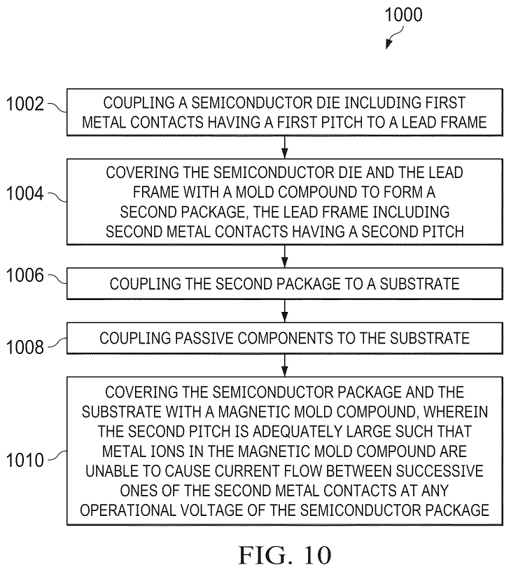

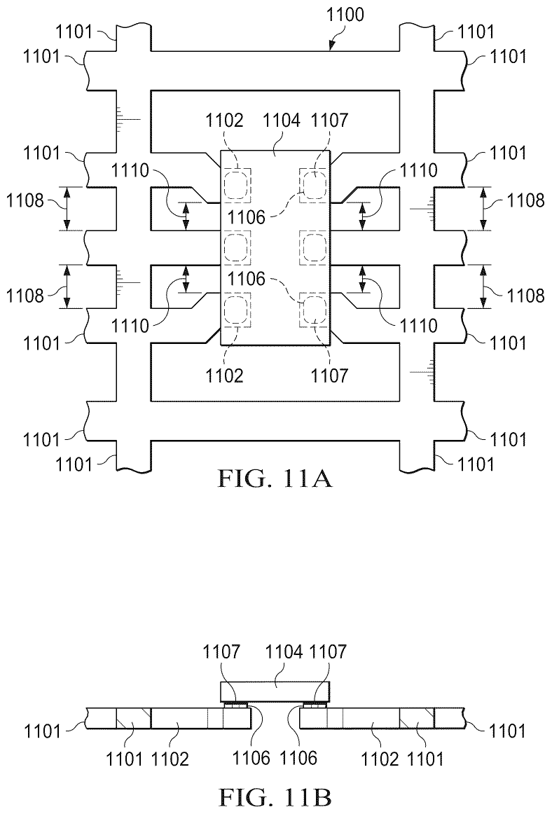

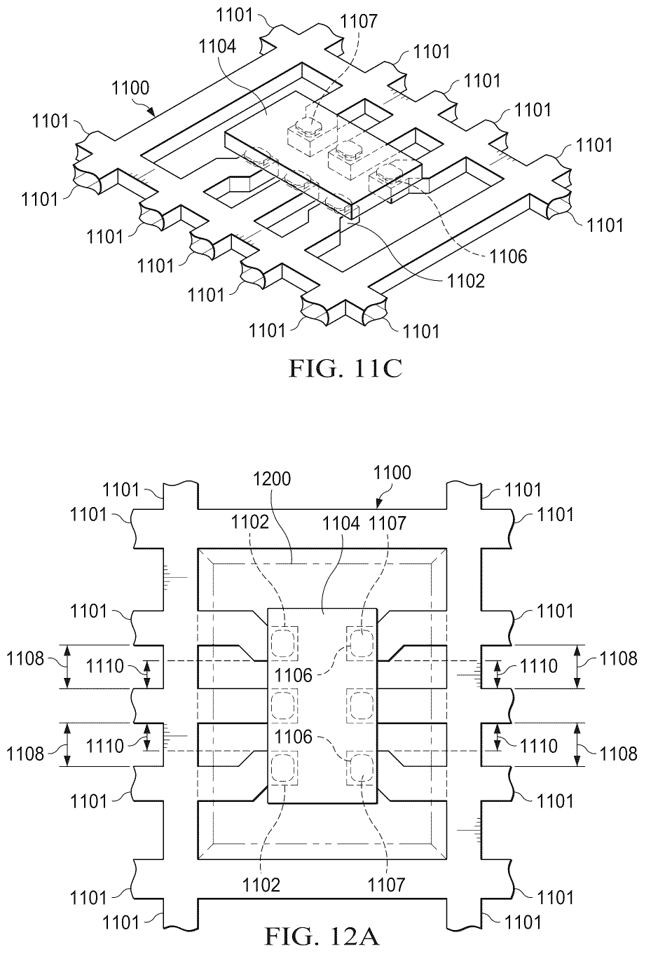

FIG. 10 is a flow diagram of a method 1000 for manufacturing an inductor module with a packaged semiconductor die, in accordance with various examples. FIGS. 11A-16C are a process flow of a method for manufacturing an inductor module with a packaged semiconductor die, in accordance with various examples. Accordingly, FIGS. 10 and 11A-16C are now described in parallel.

The method 1000 includes coupling a semiconductor die including first metal contacts having a first pitch to a lead frame (1002). FIG. 11A shows a lead frame 1100 including dam bars and/or tie bars 1101 and conductive terminals 1102 (e.g., leads). The lead frame 1100 may include any number of dam bars, tie bars, and conductive terminals, but the process flow of FIGS. 11A-16C depicts a subset of those components for clarity's sake. A semiconductor die 1104, which may be configured to perform any suitable operation, is coupled to the conductive terminals 1102 by solder bumps 1106. The semiconductor die 1104 may be oriented in a “flip-chip” configuration, meaning that a device side of the semiconductor die 1104 on which circuitry is formed faces the conductive terminals 1102. The device side of the semiconductor die 1104 may include conductive terminals 1107 that are coupled to the conductive terminals 1102 by the solder bumps 1106. The pitch, terminal widths, and inter-terminal spacing of the conductive terminals 1107 of the semiconductor die 1104 are the same as those described above for the conductive terminals of the semiconductor die within the semiconductor package 106, with the same attendant advantages and disadvantages. terminals The conductive terminals 1102 have a pitch, terminal width, and inter-terminal spacing as described above with reference to the conductive terminals 110, with the same advantages and disadvantages associated with variance outside the prescribed ranges as described above. The inter-terminal spacing 1108 has a minimum defined by one or more properties of the magnetic mold compound subsequently applied to it (e.g., magnetic mold compound 1600, described below), such as metal ion conductivity, metal ion mobility, metal ion density, and metal ion distribution. The inter-terminal spacing 1108 is adequately large to prevent leakage and shorting that would otherwise occur between consecutive ones of the conductive terminals 1102 by way of one or more metal ions in the magnetic mold compound (e.g., the magnetic mold compound 1600, described below). The inter-terminal spacing 1108 is larger than the inter-terminal spacing 1110. FIG. 11B is a profile view of the structure of FIG. 11A, in accordance with various examples. FIG. 11C is a perspective view of the structure of FIG. 11A, in accordance with various examples.

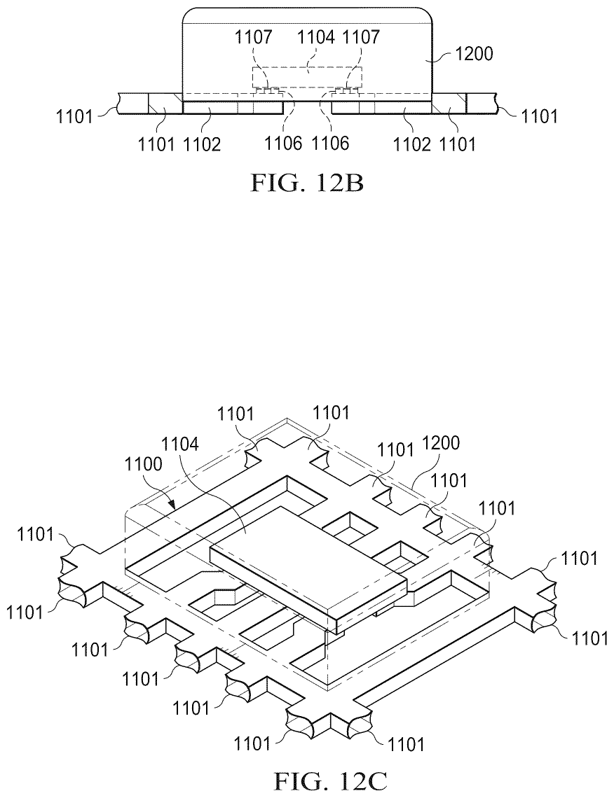

The method 1000 includes covering the semiconductor die and the lead frame with a mold compound to form a second package, the lead frame including second metal contacts having a second pitch (1004). FIG. 12A shows the structure of FIG. 11A, except that a mold compound 1200 has been applied as shown, thereby covering the semiconductor die 1104 and portions of the conductive terminals 1102. The mold compound 1200 may be applied using a mold injection process and with a mold chase, for example. The mold compound 1200 is a non-magnetic mold compound, meaning that the mold compound 1200 lacks materials (e.g., iron ions) that define a magnetic mold compound. FIG. 12B is a profile view of the structure of FIG. 12A, in accordance with various examples. FIG. 12C is a perspective view of the structure of FIG. 12A, in accordance with various examples.

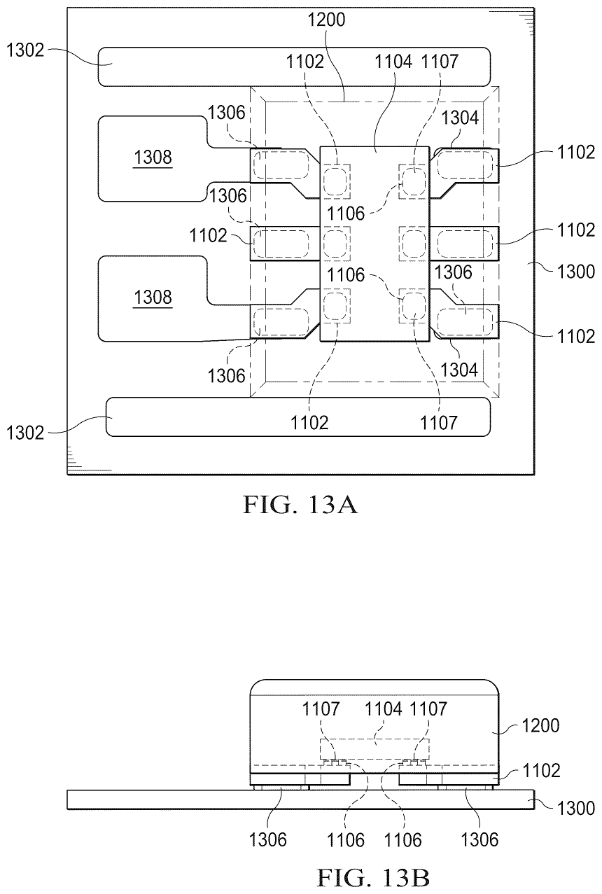

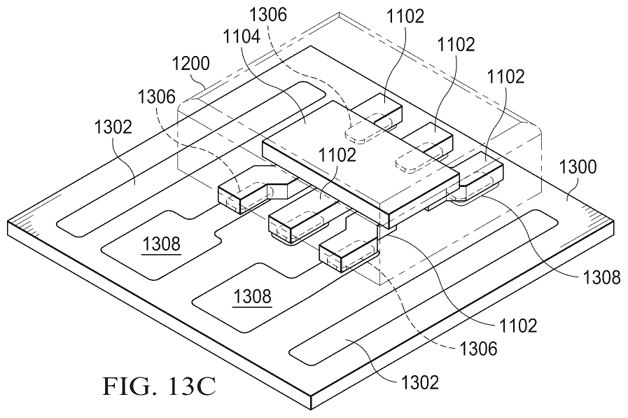

The method 1000 includes coupling the second package to a substrate (1006). FIG. 13A shows the structure of FIG. 12A, except that the structure of FIG. 12A (with dam/tie bars 1101 trimmed off) has been coupled to a substrate 1300. The description provided above for the substrate 109 also applies to the substrate 1300, and thus the substrate 1300 is not described in detail here. The substrate 1300 may include conductive terminals 1302, 1304, and 1308. The structure of FIG. 12A is coupled to the conductive terminals 1304, such as by solder bumps 1306 on the conductive terminals 1102. FIG. 13B is a profile view of the structure of FIG. 13A, in accordance with various examples. FIG. 13C is a perspective view of the structure of FIG. 13A, in accordance with various examples.

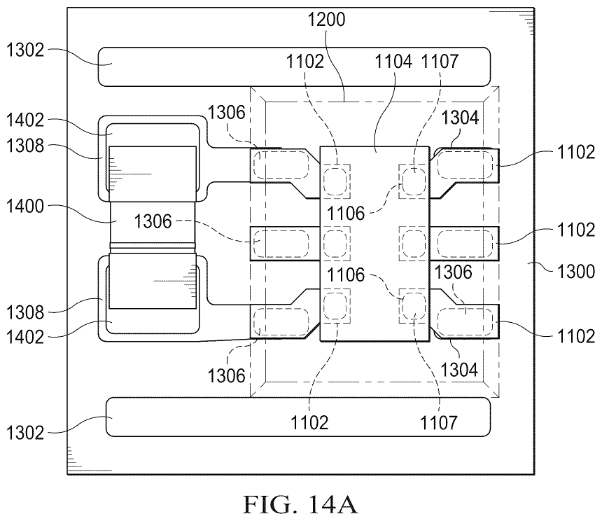

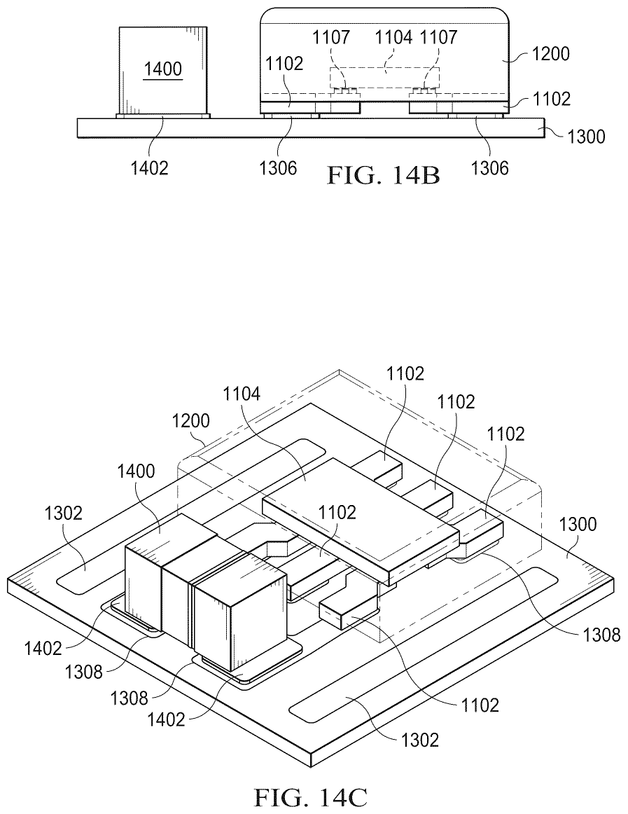

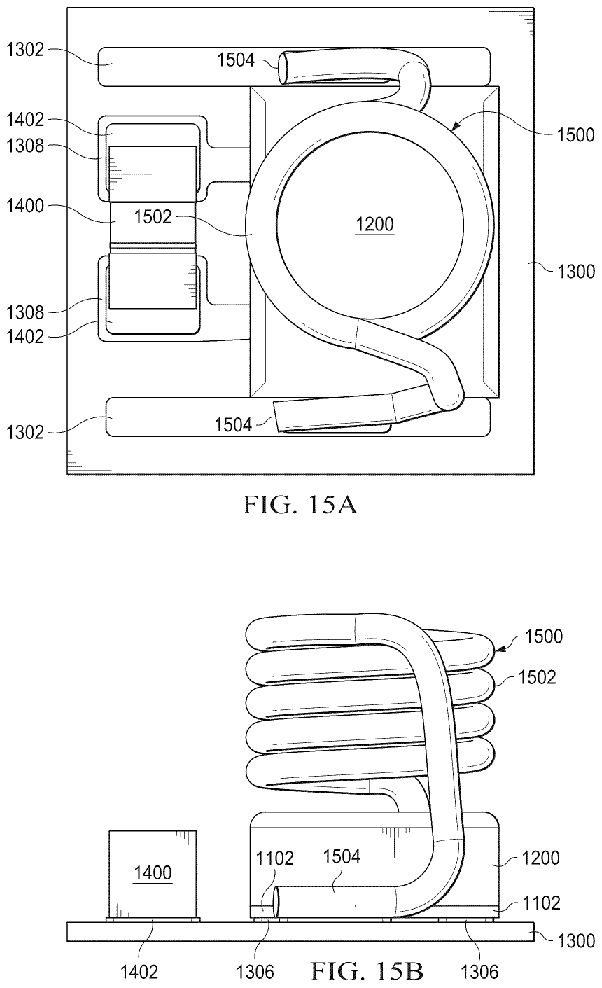

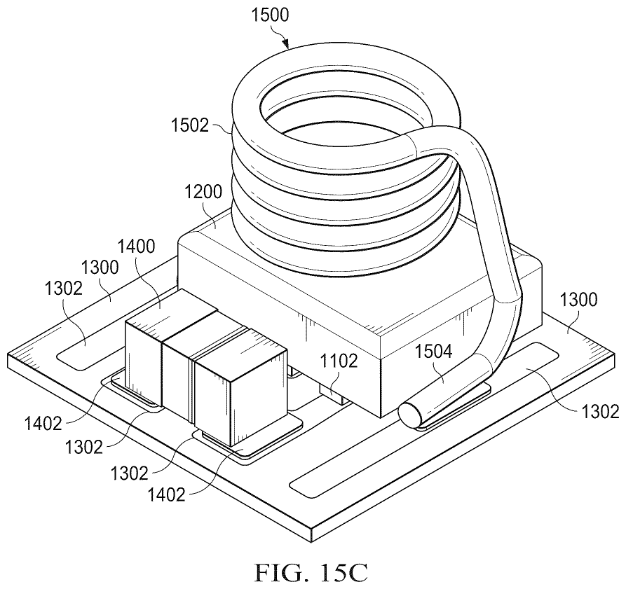

The method 1000 includes coupling passive components to the substrate (1008). FIG. 14A depicts a capacitor 1400 coupled to the substrate 1300, and more specifically, to the conductive terminals 1308, by solder bumps 1402, as shown. FIG. 14B is a profile view of the structure of FIG. 14A, in accordance with various examples. FIG. 14C is a perspective view of the structure of FIG. 14A, in accordance with various examples. FIG. 15A depicts an inductor 1500 comprising a coil portion 1502 and terminals 1504 coupled to the conductive terminals 1302 of the structure of FIG. 14A, in accordance with various examples. The inductors 115 and 512, described above, are examples of the inductor 1500, although the scope of this disclosure is not limited to any particular type of inductor. The terminals 1504 may be coupled to the conductive terminals 1302 by solder bumps, for example. FIG. 15B is a profile view of the structure of FIG. 15A, in accordance with various examples. FIG. 15C is a perspective view of the structure of FIG. 15A, in accordance with various examples. Additional or different types of passive components may be coupled to the substrate 1300, as desired.

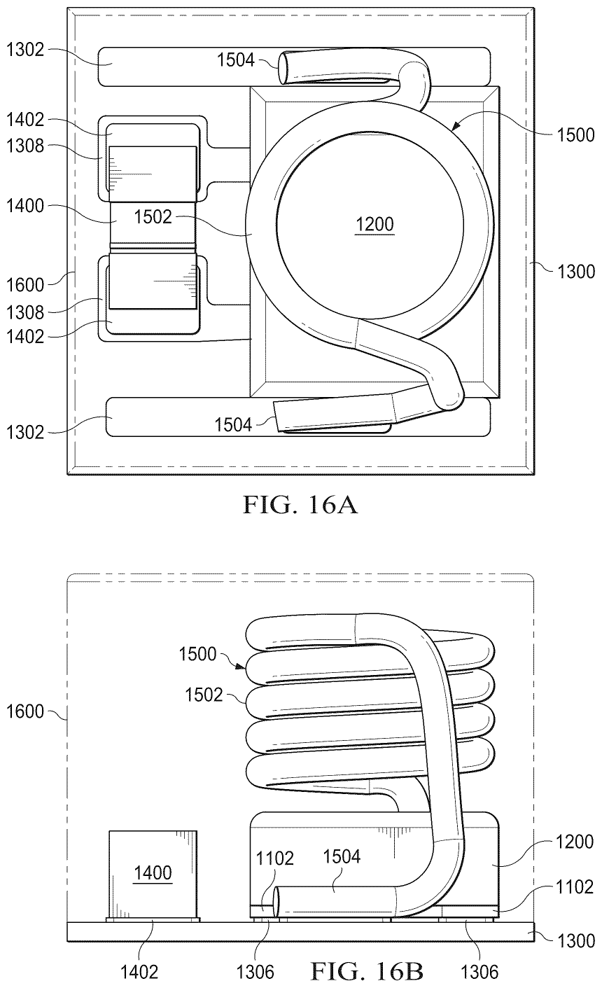

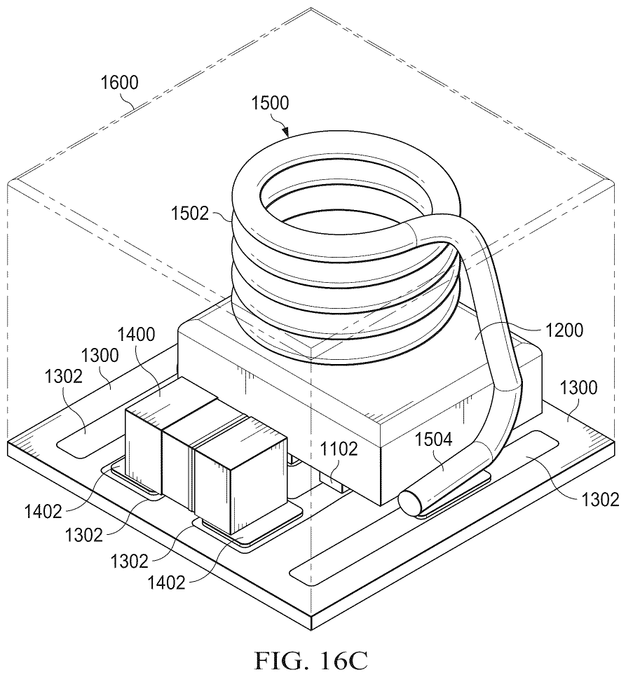

The method 1000 includes covering the semiconductor package and the substrate with a magnetic mold compound (1010). The second pitch is adequately large such that metal ions in the magnetic mold compound are unable to cause current flow between successive ones of the second metal contacts at any operational voltage of the semiconductor package (1010). FIG. 16A depicts the structure of FIG. 15A, except with the addition of a magnetic mold compound 1600. The magnetic mold compounds 122 and 518 are examples of the magnetic mold compound 1600, although other types of magnetic mold compounds also may be useful. Because the conductive terminals 1102 are adequately spaced apart from each other, the risk of current leakage and/or electrical shorts therebetween is mitigated, even in the presence of the magnetic mold compound 1600, and at any operational voltage of the package. Thus, the semiconductor die 1104 may have any desired geometry and pitch of conductive terminals and may be readily re-designed as desired with new semiconductor dies having different geometries and conductive terminal pitches, without concern for electrical leakage or electrical shorts between the conductive terminals of the die, as the non-magnetic mold compound covering the semiconductor die 1104 operates as a barrier against the magnetic mold compound 1600 and the metal ions of the magnetic mold compound 1600. Consequently, such re-designs do not require the same degree of qualification procedures as would a device that lacks the features described herein. FIG. 16B is a profile view of the structure of FIG. 16A, in accordance with various examples. FIG. 16C is a perspective view of the structure of FIG. 16A, in accordance with various examples.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

While certain components may be described herein as being of a particular process technology, these components may be exchanged for components of other process technologies. Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

In this description, unless otherwise stated, “about,” “approximately” or “substantially” preceding a parameter means being within +/−10 percent of that parameter. Modifications are possible in the described examples, and other examples are possible within the scope of the claims.

What is claimed is:

1. A semiconductor package, comprising:
a substrate;
a second semiconductor package coupled to the substrate, the second semiconductor package comprising a semiconductor die including first metal contacts coupled to second metal contacts of the second semiconductor package;
a magnetic mold compound covering the substrate and the second semiconductor package, the magnetic mold compound contacting the second metal contacts; and
an inductor coil having first and second terminals coupled to the substrate, the second semiconductor package in between the first and second terminals of the inductor coil.

2. The semiconductor package of claim 1, further comprising a non-magnetic mold compound covering the second semiconductor package.

3. The semiconductor package of claim 1, wherein the substrate includes multiple layers of metal interconnected by vertical vias and further includes build-up film contacting the multiple layers of metal and the vertical vias, and wherein the substrate is not a printed circuit board.

4. The semiconductor package of claim 1, wherein each of the first and second terminals is twisted in three-dimensional space.

5. The semiconductor package of claim 1, wherein the semiconductor package is an inductor module.

6. The semiconductor package of claim 1, wherein the first metal contacts have a first pitch ranging from 100 microns to 400 microns.

7. The semiconductor package of claim 1, wherein consecutive ones of the second metal contacts are spaced apart by at least 0.2 mm and are at least 0.2 mm wide.

8. The semiconductor package of claim 1, wherein a second pitch of the second metal contacts has a minimum defined by one or more properties of the magnetic mold compound selected from the group consisting of: metal ion conductivity, metal ion mobility, metal ion density, and metal ion distribution.

9. The semiconductor package of claim 1, wherein the magnetic mold compound includes iron ions at a packing fraction ranging from 70% to 95%.

10. The semiconductor package of claim 1, further comprising a passive component coupled to the substrate.

11. The semiconductor package of claim 1, wherein the magnetic mold compound operates as a magnetic core for the inductor coil.

12. A semiconductor package, comprising:
a substrate;
a capacitor coupled to the substrate;
a second semiconductor package coupled to the substrate and including a semiconductor die, the semiconductor die including first metal contacts having a first pitch, the second semiconductor package including second metal contacts having a second pitch; and
a magnetic mold compound covering the substrate and the second semiconductor package and contacting the second metal contacts,
wherein the second pitch prevents leakage and shorting that would otherwise occur between consecutive ones of the second metal contacts by way of one or more metal ions in the magnetic mold compound, and wherein the first pitch is smaller than the second pitch.

13. The package of claim 12, further comprising an inductor coupled to the substrate and having first and second terminals twisting in three-dimensional space as they extend from a coil portion of the inductor toward the substrate, the first and second terminals on opposing sides of the second semiconductor package.

14. The package of claim 12, wherein the second semiconductor package includes a non-magnetic mold compound.

15. The package of claim 12, wherein the substrate comprises a build-up film and is not a printed circuit board.

16. The package of claim 12, wherein the first pitch ranges from 100 microns to 400 microns.

17. The package of claim 12, wherein the second metal contacts are spaced apart by at least 0.2 mm.

18. A method for manufacturing a semiconductor package, comprising:
coupling a semiconductor die to a lead frame, the semiconductor die including first metal contacts having a first pitch;
covering the semiconductor die and the lead frame with a mold compound to form a second package, the lead frame including second metal contacts having a second pitch;
coupling the second package to a substrate; and
covering the semiconductor package and the substrate with a magnetic mold compound,
wherein the second pitch prevents metal ions in the magnetic mold compound from causing current flow between successive ones of the second metal contacts at any operational voltage of the semiconductor package, the second pitch larger than the first pitch.

19. The method of claim 18, wherein the mold compound is a non-magnetic mold compound, and wherein the substrate includes a build-up film and is not a printed circuit board.

20. The method of claim 18, further comprising coupling a passive component to the substrate, the second package in between first and second terminals of the passive component.

21. The method of claim 18, wherein the semiconductor package is an inductor module.
